(19) United States
(12) Patent Application Publication
(10) Pub. No.: US 2026/0282589 A1
(43) Pub. Date: Sep. 17, 2026

(54) ELECTROMAGNETIC RADIATION SENSOR DEVICE WITH PHOTODIODES OPERABLE IN PHOTOVOLTAIC MODE

(71) Applicant: EYE4NIR S.r.l., Calolziocorte (LC) (IT)

(72) Inventors: Andrea BALLABIO, Dolzago (LC) (IT); Andrea DE IACOVO, Roma (RM) (IT)

(73) Assignee: EYE4NIR S.r.l., Calolziocorte (LC) (IT)

(21) Appl. No.: 19/475,410

(22) PCT Filed: Apr. 17, 2024
(86) PCT No.: PCT/IB2024/053753

§ 371 Date: Oct. 14, 2025

(30) Foreign Application Priority Data
Jun. 5, 2023 (IT) 102023000011346

(51) Int. Cl. H10F 39/00

(52) U.S. Cl. CPC H10F 39/811; H10F 39/8033

(57) ABSTRACT

An electromagnetic radiation sensor device (10) is described, comprising: a first photodiode (PD1) comprising a first semiconductor having a first forbidden band and having a first terminal (A1) connected to ground (GND) and a second terminal (C1); a second photodiode (PD2) comprising a second semiconductor having a second forbidden band and having a third terminal (A2) connected to a readout terminal (SNS) and a fourth terminal (C2) in direct contact with said second terminal (C1); a control device (CT) comprising: a control terminal (CTR) to receive a control voltage (VCTR) , a terminal connected to ground (GND) and a control terminal (D) connected to the second terminal (C1). In which the sensor device (10) such to assume the following operating conditions: a first condition in which the first photodiode (PD1) assumes a photovoltaic configuration to generate a first photo-current (Iph) and the second photodiode (PD2) is inhibited from generating a photo-current; a second condition in which the control device (CT) short-WO circuits the first photodiode (PD1) to ground and the second photodiode (PD2) assumes a photovoltaic configuration to generate a second photo-current (Iph) which is such that it reaches the readout terminal (SNS).

### TECHNICAL FIELD

The present invention relates to electromagnetic radiation sensors of the dual photodiode type.

### STATE OF THE ART

Dual photodiode electromagnetic radiation sensors perform the detection of an optical signal in two different spectral bands.

The first demonstration of how the use of duel photodiodes in back-to-back configuration enables the detection of an optical signal in two different spectral bands is reported in the article J.C. Campbell et al. ‘Dual-wavelength demultiplexing InGaAsP photodiode’, Applied Physics Letters 34, 401 (1979).

This article describes the use of two layers of InGaAsP (with different concentrations of the individual chemical elements) as photosensitive elements in the 0.8-1.1 μm and 1.0-1.3 μm bands. The structure is deposited on an InP substrate and has three independent metal contacts.

The paper E. R. Blazejewski et al., ‘Bias-switchable dual-band HgCdTe infrared photodetector’, J. Vac. Sci. Tech. B, 10, 1626 (1992 ) describes a back-to-back configuration used to realise a mid-infrared and far-infrared active optical sensor using two HgCdTe alloys deposited on a CdZnTe substrate as active layers. In this case, the device is photosensitive in the 2-4.3 μm and 4.5-8.2 μm bands.

The paper L. Colace et al., ‘Solid state wavemeter with InGaAsP/InGaAs two-diode heterostructure’, Electronics Letters 38.735 (2002) describes a back-to-back structure using two layers of InGaAsP with different band gaps deposited on InP to measure the wavelength of a laser in the 30 nm range.

Document U.S. Pat. No. 6,342,720 describes a photodetector consisting of a double diode composed of a silicon Schottky diode and a PIN-type SiGe diode.

Document U.S. Pat. no. 6,043,517 discloses a photodetector that operates for two wavelength ranges and consists of two detectors arranged one above the other. A silicon Schottky diode forms a first detector that absorbs light with a wavelength of less than 0.9 μm. A second detector (a Si/SiGe diode) absorbs light with a wavelength greater than 1 μm and less than 2 μm.

Paper E. Talamas Simola et al. ‘Voltage-tunable dual-band Ge/Si photodetector operating in VIS and NIR spectral range’ Vol. 27, No. 6; 18 Mar. 2019, OPTICS EXPRESS 8529, describes a device having a germanium-on-silicon epitaxial structure consisting of two photodiodes connected back-to-back and such that it operates as a photodetector for a broad wavelength band.

WO-2022-024025 describes a dual-diode device capable of selecting the absorption band by means of the voltage applied to the device itself, exploiting a back-to-back electronic diode configuration.

As is well known, photodiodes can generate a dark current, i.e. an electric current independently of the photogeneration of interest. For example, in the case of germanium photodiodes, the dark current is mainly due to generation and recombination phenomena occurring both in the bulk (i.e. inside the germanium crystal) and on the surface of the germanium itself. These phenomena can be electric-field dependent and are particularly important when the diode is inversely polarised, i.e. when the photodiode operates in the photoconductive mode, as they contribute to reducing the signal-to-noise ratio of the photodetector.

More generally, a high dark current causes limits on the sensitivity of the device (in terms of the minimum amount of light that can be detected) and complicates the design of the readout electronics, which must be able to handle the dark current without becoming saturated.

Document US2021227156-A1 describes a technique that replicates the current of a reference diode (held in the dark) on each pixel in order to reduce the effect of the dark current pixel by pixel. Note that the sensor in this paper does not have a double absorption band, as it uses unipolar pixels, which by their very nature cannot operate with reversed polarity.

U.S. Pat. No. 10,225,504 discloses a dark current reduction system using dynamic electrical polarisation.

### SUMMARY OF THE INVENTION

The present invention addresses the problem of providing an electromagnetic radiation sensor, of the two photodiode type in a back-to-back configuration, which presents a reduced dark current as a result of alternative methods of realisation to those of the known art.

The present invention relates to an electromagnetic radiation sensor device as defined in independent claim 1 and its particular embodiments as defined in dependent claims 2-13.

### BRIEF DESCRIPTION OF THE DESIGNS

The present invention is hereinafter described in detail, by way of non-limiting examples, with reference to the accompanying drawings, in which

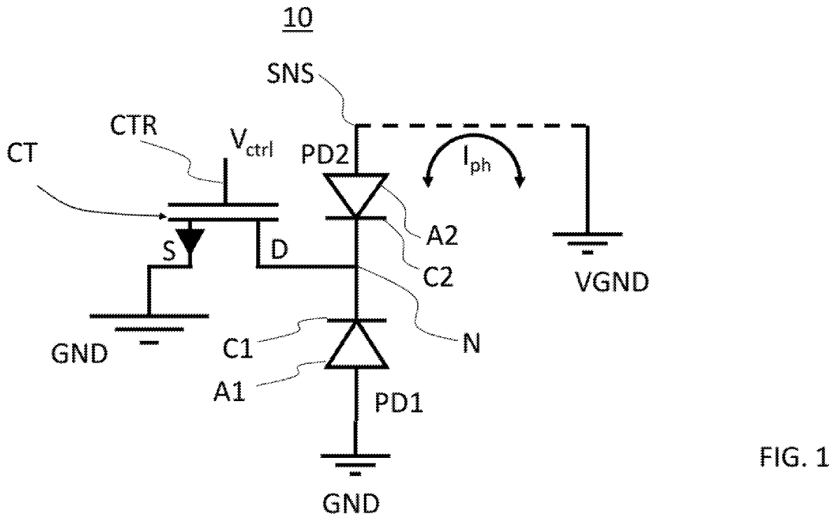

FIG. 1 illustrates the circuit diagram of a two-photodiode sensor device in back-to-back configuration;

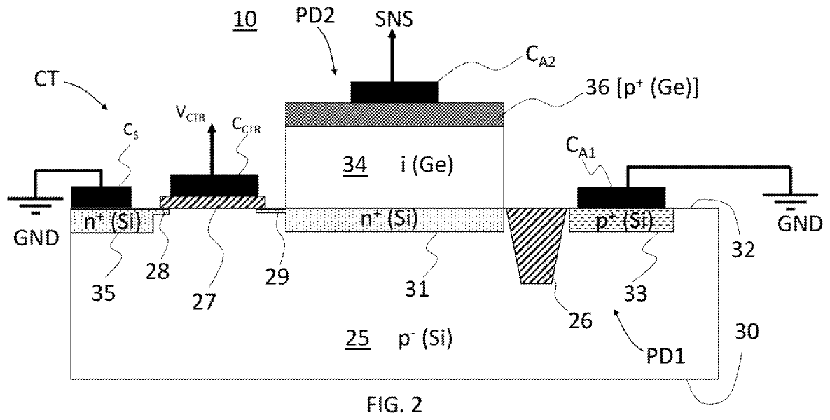

FIG. 2 shows, in a first form of realisation, a cross-section of the structure of the sensor device integrated in a substrate of semiconductor material;

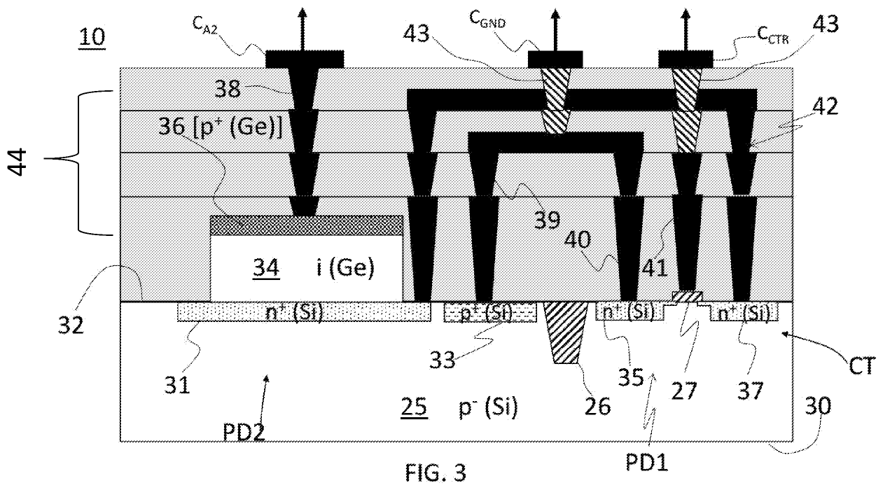

FIG. 3 shows, in accordance with a second form of realisation, a cross-section of the structure of the sensor device integrated in a substrate of semiconductor material.

### DETAILED DESCRIPTION

In this description, similar or identical elements or components will be indicated in the figures with the same identifying symbol.

FIG. 1 shows the circuit diagram of an example of a dual photodiode sensor device 10 (also referred to in the following more briefly as ‘sensor’). Sensor 10 comprises a first photodiode PD1, a second photodiode PD2 and a control device CT.

According to the example shown, the first photodiode PD1 comprises a first anode A1 connected to a ground terminal GND and a first cathode C1 connected to a node N. The second photodiode PD2 comprises a second cathode C2 connected to node N and a second anode A2 is connected to an output or sense terminal SNS. The sense terminal SNS is connected to a virtual ground VGND which may also be provided by a measuring circuit (not shown) of the current exiting the sensor 10, comprising for example a conditioning and acquisition circuit.

Specifically, the first PD1 photodiode (hereinafter also referred to as ‘PD1 diode’) is obtained from a semiconductor material with an energy gap (i.e. forbidden band) E_{g1} and the second PD2 photodiode is obtained from another semiconductor material with an energy gap E_{g2}<E_{g1}; i.e. the forbidden band E_{g1} is wider than the forbidden band E_{g2}.

The first photodiode PD1 is configured to collect and convert radiation with a wavelength λ within a first sensitivity band depending on its forbidden band E_{g1} into an electrical signal (i.e. into a photo-current Iph). This first sensitivity band lies between a first minimum wavelength Aₘᵢₙ (PD1) and a first maximum wavelength λₘₐₓ (PD1)=hc/E_{g1} (with h and c being universal constants).

The second photodiode PD2 (also referred to in the following as ‘PD2 diode’) is configured to collect and convert the radiation within a second sensitivity band into an electrical signal (a corresponding photocurrent Iph), which depends on its own forbidden band E_{g2}. The second sensitivity band includes wavelengths ranging from a second minimum wavelength λₘᵢₙ (PD2) to a second maximum wavelength λₘₐₓ (PD2)=hc/E_{g2} with λₘᵢₙ (PD2)<λₘₐₓ (PD1).

For example, in the case where the first diode PD1 is made of silicon, indicative values of λₘᵢₙ (PD1) and λₘₐₓ (PD1) are 400 nm and 1100 nm, respectively. In the case where the second PD2 diode is made of germanium, indicative values of λₘᵢₙ (PD2) and λₘₐₓ (PD2) are 400 nm and 1600 nm, respectively.

As already mentioned, photodiodes can generate a dark current, i.e. they can generate an electric current independently of the photogeneration of interest. In the case of germanium photodiodes, the dark current is mainly due to generation and recombination phenomena occurring both in the bulk (i.e. inside the germanium crystal) and on the surface of the germanium itself. These phenomena can be electric-field dependent and are particularly important in reverse polarisation, i.e. when the photodiode operates in the photoconductive mode, as they contribute to reducing the signal-to-noise ratio of the photodetector.

As will be further described with examples, the first photodiode PD1 and the second photodiode PD2 are realised in a back-to-back configuration. The term ‘back-to-back configuration’ is understood in this description to mean that the two photodiodes have their cathodes or, alternatively, their anodes in direct contact. In particular, such ‘direct contact’ can also be achieved by sharing a layer of semiconductor material between the two photodiodes, which then acts for both photodiodes as a common anode or common cathode. In the circuit schematisation of FIG. 1, a node N has been introduced to schematise a direct contact zone between the first cathode C1 and the second cathode C2.

The control device CT comprises a control terminal CTR, for applying a control voltage V_{CTR}, a first terminal S, connected to the earth terminal GND, and a second terminal D connected to the node N.

Preferably, the control device CT is a transistor and, more particularly, it is a MOSFET and the control terminal CTR is its gate terminal. For example, the control transistor CT is an N-channel MOSFET and the first terminal S is the source terminal and the second terminal is the drain terminal D. As will be seen from the realisation examples that will be described below, the first diode PD1 and the second diode PD2 can be realised using conventional CMOS (Complementary Metal-Oxide-Semiconductor) compatible semiconductor integration techniques.

In the following description, reference will be made to the example case in which the first diode PD1 is made of silicon and the second diode PD2 is made of germanium.

The first PD1 diode, being made of silicon, is such that it is able to collect and convert radiation in the visible and near-infrared into an electrical signal (i.e., the Iph current), and thus radiation having, indicatively, a minimum wavelength λₘᵢₙ (PD1) of 400 nm and a maximum wavelength λₘₐₓ (PD1) of 1100 nm. The visible VIS (Visible) band is, as is known, included in the wavelength range 400 nm-700 nm. The Near InfraRed (NIR) band extends from 700 nm to 1100 nm.

The second diode PD2, made at least partially of germanium, is such that it is able to collect and convert radiation with a minimum wavelength of λₘᵢₙ (PD2) 400 nm and a maximum wavelength λₘₐₓ (PD2) of 1600 nm into an electrical signal (i.e., current Iph).

As is well known, the Near InfraRed (NIR) band extends from 700 nm to 1100 nm, while the Short Wave InfraRed (SWIR) band is included in the 1100 nm-3000 nm wavelength range.

In other words, sensor 10, if fabricated using silicon for the photodiode PD1 and germanium for the photodiode PD2 as shown in the particular realisation form in FIG. 1, can operate in the visible, near-infrared to part of the short-wave infrared.

With regard to the operation of sensor 10, note that no external voltage is applied to the sense terminal SNS and that, therefore, the potential difference between the first anode A1 and the second anode A2 is zero.

In a first operating condition, the control transistor CT is switched off as a zero control voltage VCTR is applied to the control terminal CTR.

In this situation, the first photodiode PD1 and the second photodiode PD2 are connected in series. Due to the alignment between the energy bands of the two different materials in contact with the two photodiodes, only the first photodiode PD1 (which has a higher energy band than the second photodiode PD2) is able to generate a relative photo-current, whereas the second photodiode PD2 (in germanium, according to the example) is not able to generate photo-current, i.e. it is in an inhibition condition. In more detail, the different physical characteristics of the two semiconductor materials (width of the forbidden band, relative dielectric constant, intrinsic density of free carriers) mean that, once placed in contact, an electric field develops at the interface such that, in the absence of externally applied polarisation, photocurrent generation is only possible by the first photodiode PD1. Even more specifically, the alignment between the energy bands of the two semiconductors and the presence of a native electric field (built-in field) at the interface between the two semiconductors mean that the charges photogenerated by the second photodiode PD2 cannot flow between the sense terminal SNS and the ground terminal GND and, consequently, cannot be measured as a photo-current.

The first photodiode PD1 is in the photovoltaic mode, as it is not polarised and when hit by radiation within the first sensitivity band associated with the first photodiode PD1 itself generates a first photo-current Iph. Note also that being in the photovoltaic mode, the first photodiode PD1 does not have a dark current contrary to what it would have if it were operating in the photoconductive mode.

On the other hand, as mentioned above, the second photodiode PD2 cannot generate any photo-current, even if invested by radiation included in the second sensitivity band (to simplify, this is due to the low probability of collecting photogenerated charges from the second photodiode PD2 due to the conformation of the energy bands) Furthermore, note that in this situation of no external polarisation, the second photodiode PD2 has no dark current: to be checked.

The second photodiode PD2, although not able to generate photo-currents, is such that it is traversed by the Iph photo-current generated by the first photodiode PD1; photo-current then reaches the sense terminal SNS, from where it can be supplied to the conditioning and acquisition circuit.

In this first operating condition, sensor 10 shows a sensitivity band that corresponds to that of the first photodiode PD1, i.e. the visible VIS and part of the near-infrared NIR band.

In a second operating condition, the control device CT operates in such a way that it short-circuits the first photodiode PD1 to ground GND. More specifically, a control voltage VCTR greater than a threshold value of the control transistor CT itself is applied to the control terminal CTR so that it operates in its triode region. In this situation, the control transistor CT electrically connects the source terminal S with the drain terminal D connected to node N and then connects the two cathodes C1 and C2 with the ground terminal GND. Again, no external bias voltage is applied to the first photodiode PD1 and the second photodiode PD2.

In this second condition, an alignment of the energy bands of the two photodiodes occurs that differs from the proceeding one and is such that the second photodiode PD2 is brought into the photovoltaic mode. Thus, when hit by radiation within the second sensitivity band, the second photodiode PD2 generates a corresponding photo-current Iph. This photo-current Iph flows into the circuit formed by the control transistor CT and the second photodiode PD2 so that it can be drawn from the sense terminal SNS.

Note that, in this condition, the cathode C2 of the second photodiode PD2 is directly connected to the ground terminal GND via the control transistor CT; therefore, the photogenerated charges from the second photodiode PD2 do not have to pass through the first photodiode PD1 in order to be collected at the GND ground terminal and generate a measurable photocurrent through the sense terminal SNS. In other words, the activation of the control transistor CT allows the photocurrent generated by the second photodiode PD2 to be measured via the sense terminal SNS while inhibiting the collection of carriers photogenerated by the first photodiode PD1.

It should also be noted that, operating in photovoltaic mode, the second photodiode PD2 does not generate dark current, unlike if it operated in photoconductive mode.

Note that in this second operating condition, the first photodiode PD1 is also in photovoltaic mode, and the photo-current generated by it (when hit by radiation within the first sensitivity band) flows through the control transistor CT, which effectively short-circuits the diode PD1, and does not flow through the second photodiode PD2 or reach the sense terminal SNS.

In the second operating condition, sensor 10 has a sensitivity band equal to only the second sensitivity band associated with the second diode PD2, i.e., in accordance with the example described, a band extending from near-Infrared NIR to short-wave infrared SWIR.

As clarified by the above description, the switching between the sensitivity bands of the sensor 10 is obtained according to the control voltage VCTR applied to the control terminal CTR. This control voltage VCTR assumes, in one operating condition, a voltage less than the threshold voltage of the control transistor CT while, in the other operating condition, it assumes a value greater than this threshold voltage.

FIG. 2 refers to a first example of a sensor structure 10, which can be realised using conventional semiconductor material integration techniques, compatible with CMOS integration techniques. In the following description, reference will be made, by way of example, to the materials silicon and germanium.

As shown in FIG. 2, the sensor 10 comprises a substrate 25 made of a first semiconductor material (in the example, shown, silicon) having, for example, a p-type doping-(weak doping). The substrate 25 defines a first face 30 and an opposing second face 32.

The first face 30 constitutes an exposed region from which the electromagnetic radiation penetrates. Note that the substrate 25 of sensor 10 in FIG. 3 could be n-type, according to another form of implementation.

A first doped region 31 is formed in the substrate 25, of the same material as the substrate, but with a doping opposite to that of the substrate 25, i.e., according to the example, with a doping of type n, preferably, strongly doped n⁺. The first doped region 31 extends from the second face 32 of the substrate 25 towards the interior of the substrate itself, without reaching, the first face 30.

Note that this first doped region 31 is intended to act as a common electrode (according to the example, a cathode electrode) to the first diode PD1 and the second diode PD2 and thus, according to the circuit schematic in FIG. 1 also as a node N.

A second doped region 33 is formed within the substrate 25 having, according to the example, a doping of the same type as the substrate 25 but higher, i.e. a p+ doping. The second doped region 33 develops from the second face 32 towards the interior of the substrate 25 without reaching the first face 30, with a depth equal to, for example, that of the first doped region 31.

For example, the second doped region 33 develops inside the substrate 25 so that it laterally surrounds, in an open loop, the first doped region 31.

Note that the second doped region 33 is intended to act as an additional electrode (in this example, as an anode) for the first diode PD1.

Furthermore, the sensor 10 comprises a layer in a second semiconductor material 34 (in germanium, according to the example) arranged on the second face 32 of the substrate 25 and so as to be in contact with the first doped region 31, covering it entirely. Such a germanium layer 34 is, for example, in intrinsic germanium. Note that, according to the example, the germanium layer 34 is intended to operate as the intrinsic layer of the second diode PD2.

Above the intrinsic germanium layer 34 is arranged a doped layer 36 (in germanium) having, according to the example, a high p-type doping (i.e., a p+ doping). The doped layer 36 is intended to act as an anode for the second diode PD2.

An isolation trench 26, preferably made of silicon dioxide, which electrically isolates the second doped region 33 from the first doped region 31, is also made within the substrate 25. Said isolation trench 26 is developed around the first doped region 31 in such a way as to interrupt the substrate 25 and prevent horizontal movement of electrical charges towards the second doped region 33. The isolation trench 26 may be developed in an open ring shape, similar to that described for the doped region 33.

A third doped region 35 is formed in the substrate 25, of the same material as the substrate, but with a doping opposite to that of the substrate 25, i.e., according to the example, with a doping of type n, preferably, strongly doped n+. The third doped region 35 extends from the second face 32 of the substrate 25 towards the interior of the substrate itself, without reaching the first face 30. This third doped region is intended to act as the source terminal of the control transistor CT.

On the second face 32, a layer of insulating material 27 (e.g. silicon dioxide) is made which has a central portion facing a portion of the substrate 25 which is intermediate between the first doped region 31 and the third doped region 35. Preferably, the insulating material layer 27 has side portions facing a first extension 28 of the third doped region 35 and a second extension 29 of the first doped region 31, respectively. The first extension 28 has a doping equal to that of the third doped region 35 but has a reduced thickness compared to that region. The second extension 29 has the same doping as the first doped region 31 but has a reduced thickness relative to that region.

The sensor 10 has metal contacts arranged to contact the second doped region 33 at said second face 32, the doped layer 36 and the layer of insulating material 27.

In particular, sensor 10 has a first metal layer arranged above the second doped region 33 (i.e., in the example, part of the anode of the first diode PD1), so as to form a first contact C_{A1}, connected to the GND ground terminal.

Furthermore, the sensor 10 comprises a second metal layer arranged above the doped layer 36 (i.e., in the example, the anode of the second diode PD2) so as to form a second contact C_{A2} also corresponding to the sense terminal SNS of FIG. 1. A third metal layer arranged above the electrical insulation layer 27 forms a control contact C_{CTR}, corresponding to the control terminal D of FIG. 1.

Above the third doped region 35 is a fourth metal layer that forms, in the example, a source contact C_{S} of the control transistor CT.

In summary, the first diode PD1 comprises the first doped region 31 (i.e., the first cathode C1), a portion of the substrate 25 and the second doped region 33 (forming the first anode A). The second diode PD2 comprises the first doped region 31 (i.e., the second cathode C2), the intrinsic germanium layer 34, the doped layer 36 (i.e., the second anode A2). Note that the first doped region 31 has the role of a common cathode electrode to both the first diode PD1 and the second diode PD2.

The control transistor CT comprises the third doped region 35 which constitutes the source terminal, the control contact CTR which constitutes the gate terminal and the first doped region 31 which also acts as the drain contact.

It should also be noted that the fact that the first doped region 31 is common to the first photodiode PD1, the second photodiode PD2 and also the control transistor CT is very advantageous because it makes it possible to increase the density of devices that can be realised on a single substrate.

FIG. 3 refers to another form of realisation of sensor 10, whereby the control transistor CT has no common layers with the two photodiodes PD1 and PD2. In FIG. 3, the same numerical references were used as in FIG. 2 to represent equal layers.

The two photodiodes PD1 and PD2 are realised in a similar manner as described with reference to FIG. 2, as the branch engineer can recognise from FIG. 3. The control transistor CT comprises, in addition to the third doped region 35 (which, as already described, operates as a source terminal), also a fourth doped region 37 (according to the example, with a n-type doping, preferably, strongly doped n⁺) which operates as a drain terminal.

In the realisation of FIG. 3, the doped layer 36 (i.e., in the example, the anode of the second diode PD2) is connected to the second anode contact C_{A2} by a first vertical metallisation 38, which passes through several layers of insulating material (preferably silicon dioxide) 44.

A metallic ground contact C_{GND} is electrically connected, via a second vertical metallisation 39, to the second doped region 33 and via a third vertical metallisation 40, to the third doped region 35.

The control contact C_{CTR} contacts the insulating material layer 27 by means of a fourth vertical metallisation 41. An integrated metal structure 42 contacts the first doped region 31 (i.e., according to the example, the cathode of the two photodiodes) with the fourth doped region 37, i.e., the drain terminal of the control transistor CT.

In FIG. 3, metal regions 43 separated (in the direction orthogonal to the plane of FIG. 3) from the metal structure 42 are also shown. With regard to the integration techniques that can be employed for the structures of FIG. 2 and FIG. 3, consider that, for example, the first doped region 31, the second doped region 33, the third doped region 35, the doped layer 36, the fourth doped region 37 can be formed by means of implantation techniques and/or by spin-on dopant and/or deposition techniques (including epitaxy, sputtering, evaporation).

The intrinsic germanium layer 34 can be realised by chemical and/or physical deposition techniques such as epitaxy, sputtering, evaporation or even transfer as wafer bonding.

It should be noted that although in the foregoing description 1 reference was made to the use of silicon and germanium, the sensor 10 may be fabricated from other semiconductor materials. For example, other possible materials capable of satisfying the aforementioned relationships between the photo-response bands of the first diode PD1 and/or the second diode PD2 include semiconductor materials chosen from one of the following types:
(a) III-V semiconductors (e.g. GaAs, InAs, InP) and their alloys;
(b) II-VI semiconductors (e.g. ZnSe, ZnTe, CdSe, CdTe, HgTe, PbS, PbSe) and their alloys;
(c) IV semiconductors (e.g. Si, Ge, GeSn) and their alloys.

The embodiment of the sensor 10 described above with reference to FIGS. 2 and 3 are not complex to manufacture and, in addition, have the advantage of presenting the sensor's metal contacts on the same side of the substrate 25 in which it is integrated, thus resulting in a “planar” type.

The flatness of sensor device 10 allows it to be monolithically integrated on silicon substrates with other electronic circuits manufactured using CMOS processing techniques. This makes it possible to simultaneously manufacture the sensor device and the conditioning and acquisition electronics on the same substrate, using similar processing technologies that represent an industry standard.

The sensor device 10 can be connected to the external circuitry via micro-soldering techniques (bump-bonding, wire bonding, Cu—Cu bonding) or via an electronic connection board (PCB).

With regard to possible uses, sensor 10 can be used to realise a camera capable of acquiring images in two different bands (e.g. in VIS-NIR and SWIR). In addition, sensor 10 can be used in a spectrum detection system for spectral analysis of incident radiation or to realise a hyperspectral imaging sensor system.

For example, for the realisation of the two-band image acquisition camera or the hyperspectral imaging sensor system, a plurality of sensors 10 with a structure similar to the one described above can be integrated into the same substrate 25, resulting in a two-dimensional array.

Sensor 10 has the advantage of being able to operate on two different sensitivity bands with very low dark current in both bands, thus achieving a higher sensitivity than can be achieved with known techniques.

The increase in sensitivity allows the use of sensor 10 in more critical conditions than those required by current technology. In fact, an increase in sensitivity allows sensor 10 to be used in reduced illumination such as, for example, in the automotive sector, where it is often not possible to use both VIS and SWIR illumination systems.

Another advantage is that sensor 10 can be realised with a monolithic integration approach and is compatible with the manufacturing processes typical of CMOS electronics.

### LEGEND OF FIGURE NUMBERS

dual photodiode sensor device 10
first photodiode PD1
second photodiode PD2
control device CT
first anode A1
earth terminal GND
first cathode C1
node N
second cathode C2
second anode A2
sense terminal SNS
virtual earth VGND
control terminal CTR
control voltage V_{CTR}
first terminal S
earth terminal GND
second terminal D
photo-current Iph
substrate 25
isolation channel 26
layer of insulation material 27
a first extension 28
second extension 29
first face 30
first doped region 31
second face 32
second doped region 33
layer in second semiconductor material 34
third doped region 35
doped layer 36
an initial contact C_{A1}
second contact C_{A2}
control contact C_{CTR}
source contact C_{S}
fourth doped region 37
first vertical metallisation 38
second vertical metallisation 39
third vertical metallisation 40
vertical metallisation 41
integrated metal structure 42
metal zones 43
layer of insulation material 44

1. Electromagnetic radiation sensor device (10) comprising:
a first photodiode (PD1) comprising a first semiconductor having a first band gap and having a first terminal (Al) connected to ground (GND) and a second terminal (CI);
a second photodiode (PD2) comprising a second semiconductor having a second band gap different from the first band gap and having a third terminal (A2) connected to a readout terminal (SNS) and a fourth terminal (C2) in direct contact with said second terminal (CI);
a control device (CT) comprising: a control terminal (CTR) to receive a control voltage (VCTR), a terminal connected to ground (GND) and a control terminal (D) connected to the second terminal (C1);
in which the sensor device (10) is such that to selectively assume the following operating conditions:
a first condition in which: the control device (CT) operates as an open circuit; the first photodiode (PD1) assumes a photovoltaic configuration to generate a first photo-current (Iph);
and the second photodiode (PD2) is inhibited from generating photo-current as a result of an alignment between said band gaps and is such that the first photo-current reaches the readout terminal (SNS); and,
a second condition in which the control device (CT) short-circuits the first photodiode (PD1) to ground and the second photodiode (PD2) assumes the photovoltaic configuration to generate a second photo-current (Iph) that is such that to reach the readout terminal (SNS).

2. Sensor device (10) according to claim 1, wherein:
the control device (CT) comprises a transistor configured to be off in the first condition and to assume the triode configuration in the second condition.

3. Sensor device (10) according to claim 1, wherein:
the second terminal (C1) and fourth (C2) terminal are selectively one of the following types of terminals: both anode terminals, both cathode terminals.

4. Sensor device (10) according to claim 1, wherein:
the first photodiode (PD1) is such that to have a first dark current in photoconductive configuration; and,
the second photodiode (PD2) is such having a second dark current in photoconductive configuration of higher intensity than said first dark current.

5. Sensor device (10) according to claim 2, wherein.
the first photodiode (PD1) is such that it has a first dark current in photovoltaic configuration of an intensity less than said first dark current in photoconductive configuration; and,
the second photodiode (PD2) is such as to have a second dark current in photovoltaic configuration of an intensity less than said second dark current in photoconductive configuration.

6. Sensor device (10) according to claim 1, wherein the first band gap Eg1 is greater than the second band gap Eg2.

7. Sensor device (10) according to claim 1, comprising:
a substrate (25) in the first semiconductor material such as to define a first face (12, 30) exposed to electromagnetic radiation (EMR) and a second face (32) opposed to the first face;
wherein:
the first photodiode (PD1) comprises:
a first doped region (31) included in the substrate (25) so as to extend to the first face (32) and having a doping of a first type;
a second doped region (33) included in the substrate (25) so as to extend to the second face (32), separated from the first region (31) by a portion of the substrate (25), and having a doping of a second type (p+);
the second photodiode (PD2) comprising said first doped region (31); and:
a layer in the second semiconductor material (34) arranged on the second face (32) in contact with the first doped region (31);
a doped layer (36) in the second semiconductor material having a doping of the second type (p+) and superimposed on the layer in the second semiconductor material and,
metal contacts (CAI; CGND, CA2;) arranged to contact the second doped region (33), at the second face (32), and the doped layer (36).

8. Device according to claim 7, wherein the first doped region (31) is such that it acts as a common anode/cathode to the first photodiode (PD1) and the second photodiode (PD2).

9. Sensor device (10) according to claim 2, wherein said transistor (CT) comprises:
a third doped region (35) included in the substrate (25) so as to extend to the second face (32) and having doping of the first type; the third doped region is connected to said grounded terminal (GND);
a fourth doped region (31; 37) included in the substrate (25) so as to extend to the second face (32) and having doping of the first type; the fourth doped region (31, 37) is connected to said control terminal (D);
a layer of electrically insulating material (27) arranged on said second face (32) and having at least a central portion facing a region of the substrate (25) interposed between the third doped region (35) and the fourth doped region (31; 37); and,
a metal contact (CCTR) arranged above said layer of insulating material (27) and connected to the control terminal (CTR).

10. Sensor device (10) according to claim 9, wherein said fourth doped region (31) is the first doped region (31) common to the first photodiode (PD1) and the second photodiode (PD2).

11. Sensor device (10) according to claim 1, wherein the first and/or second semiconductor is a material selected from one of the following types:
a) III-V semiconductors and their alloys;
b) II-VI semiconductors and their alloys; or,
c) Group IV semiconductors and their alloys.

12. Sensor device (10) according to claim 1, wherein the first and second semiconductors are chosen such that the sensor device (10) is such that it operates in the visible, near infrared up to part of the shortwave infrared.

13. Sensor device (10) according to claim 1, wherein the first photodiode (PD1) and the second photodiode (PD2) are manufactured using semiconductor material integration techniques compatible with Complementary Metal-Oxide-Semiconductor (CMOS) integration techniques.

14. Sensor device (10) according to claim 8, wherein said transistor (CT) comprises:
a third doped region (35) included in the substrate (25) so as to extend to the second face (32) and having doping of the first type; the third doped region is connected to said grounded terminal (GND);
a fourth doped region (31; 37) included in the substrate (25) so as to extend to the second face (32) and having doping of the first type; the fourth doped region (31, 37) is connected to said control terminal (D);
a layer of electrically insulating material (27) arranged on said second face (32) and having at least a central portion facing a region of the substrate (25) interposed between the third doped region (35) and the fourth doped region (31; 37); and,
a metal contact (CCTR) arranged above said layer of insulating material (27) and connected to the control terminal (CTR).

15. Sensor device (10) according to claim 14, wherein said fourth doped region (31) is the first doped region (31) common to the first photodiode (PD1) and the second photodiode (PD2).
